(19) United States
(12) Patent Application Publication
(10) Pub. No.: US 2025/0239512 A1
(43) Pub. Date: Jul. 24, 2025

(54) PACKAGE STRUCTURE

(71) Applicant: Advanced Semiconductor Engineering, Inc., Kaohsiung (TW)

(72) Inventors: Che-Neng LIU, Kaohsiung (TW); Guo-Cheng LIAO, Kaohsiung (TW)

(73) Assignee: Advanced Semiconductor Engineering, Inc., Kaohsiung (TW)

(21) Appl. No.: 18/418,129

(22) Filed: Jan. 19, 2024

(51) Int. Cl. H01L 23/498; H01L 23/00; H01L 25/065

(52) U.S. Cl. CPC H01L 23/49838; H01L 23/49822; H01L 24/08; H01L 24/48; H01L 25/0652; H01L 2224/08146; H01L 2224/08165; H01L 2224/48137; H01L 2224/48157; H01L 2924/01029; H01L 2924/096; H01L 2924/182

(57) ABSTRACT

A package structure is provided. The package structure includes a lower substrate, an upper substrate, and a chip. The lower substrate defines a lower through hole. The upper substrate is over the lower substrate and defines an upper through hole connected to the lower through hole. A portion of a top surface of the lower substrate is exposed by the upper through hole. The chip is at least partially accommodated by the upper through hole and supported by the portion of the top surface of the lower substrate.

### BACKGROUND

### 1. Technical Field

The present disclosure relates generally to a package structure.

### 2. Description of the Related Art

Currently, for manufacturing a package structure including a chip or component with input/output (I/O) terminals on opposite sides, a ceramic substrate may be manufactured to provide a specific structure for the chip or component to be disposed therein, such that the I/O terminals on opposite sides of the chip or component can be exposed by the ceramic substrate for electrical connection. However, the cost and the difficulty for manufacturing the ceramic substrate with the specific structure may be relatively high, and the brittle texture of the ceramic substrate may render the ceramic substrate relatively fragile and thus reducing the yield.

### SUMMARY

In one or more arrangements, a package structure includes a lower substrate, an upper substrate, and a chip. The lower substrate defines a lower through hole. The upper substrate is over the lower substrate and defines an upper through hole connected to the lower through hole. A portion of a top surface of the lower substrate is exposed by the upper through hole. The chip is at least partially accommodated by the upper through hole and supported by the portion of the top surface of the lower substrate.

In one or more arrangements, a package structure includes a substrate structure and a chip. The substrate structure defines a through hole including a stepped sidewall structure. The chip is disposed in the through hole and supported by the stepped sidewall structure. In a top view perspective, a center axis of the substrate structure is non-parallel to a center axis of the chip.

In one or more arrangements, a package structure includes a first substrate, a second substrate, and a chip. The first substrate defines a first through hole. The second substrate is over and physically spaced apart from the first substrate. The second substrate defines a second through hole. A center axis of the first through hole is misaligned with a center axis of the second through hole in a cross-sectional view perspective. The chip is disposed in the second through hole.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of a package structure in accordance with some arrangements of the present disclosure.

FIG. 1C is a cross-section of a package structure in accordance with some arrangements of the present disclosure.

FIG. 1D is a top view of a package structure in accordance with some arrangements of the present disclosure.

FIG. 1E is a top view of a package structure in accordance with some arrangements of the present disclosure.

FIG. 1F is a top view of a package structure in accordance with some arrangements of the present disclosure.

FIG. 1G is a perspective view of a package structure in accordance with some arrangements of the present disclosure.

FIG. 2A, FIG. 2B, FIG. 2C, FIG. 2D, FIG. 2E, FIG. 2F, FIG. 2G, FIG. 2H, and FIG. 2I illustrate various stages of an exemplary method for manufacturing a package structure in accordance with some embodiments of the present disclosure.

FIG. 3A, and FIG. 3B illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

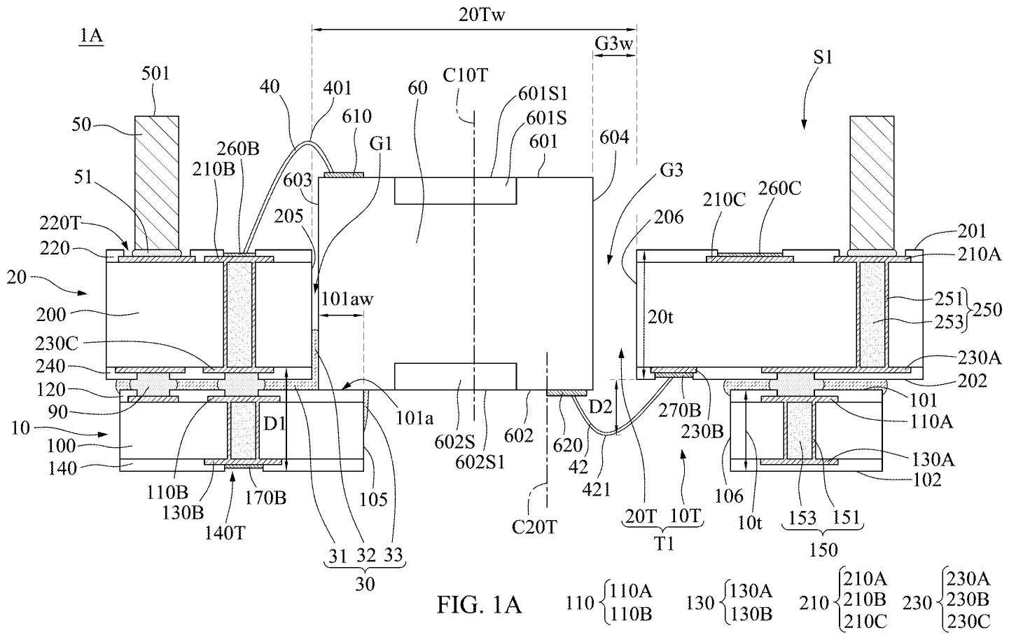

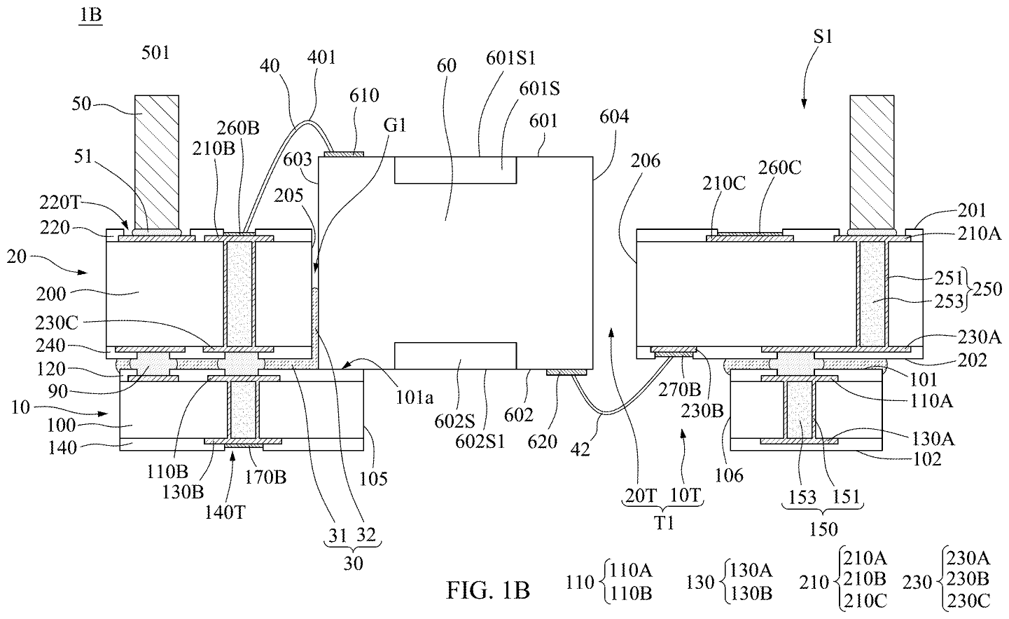

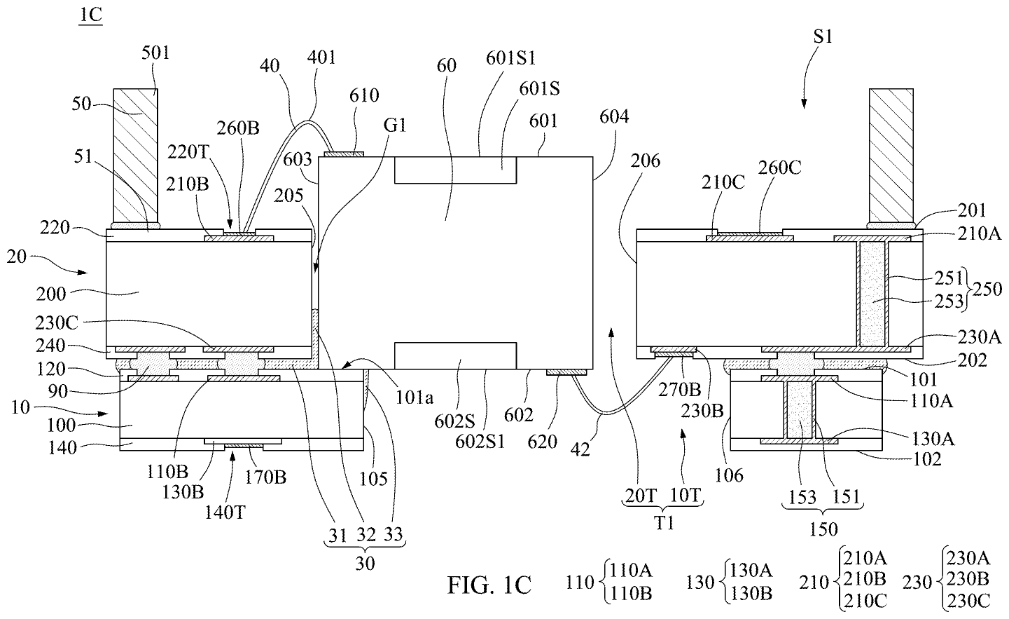

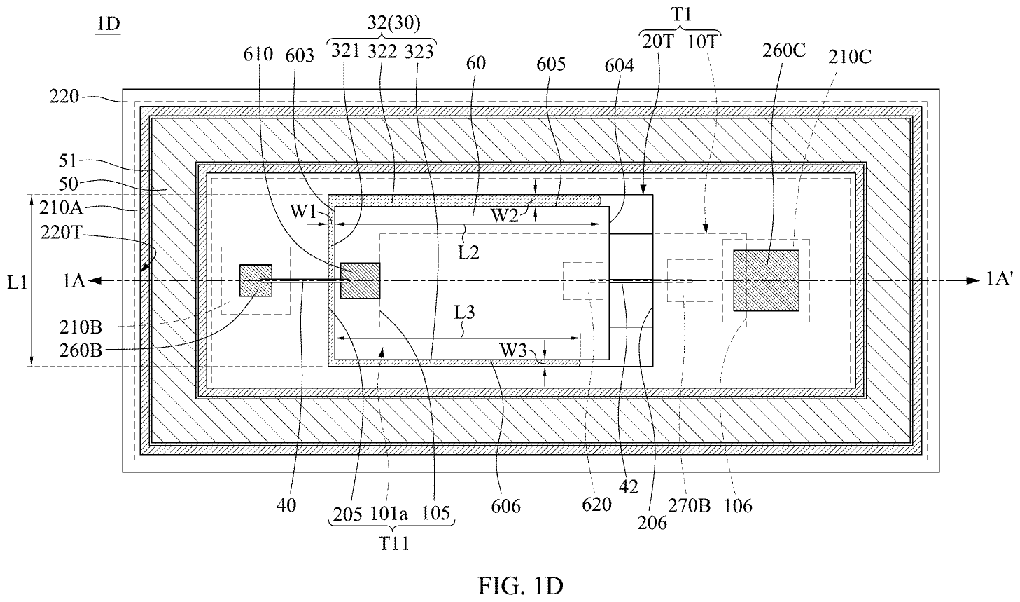

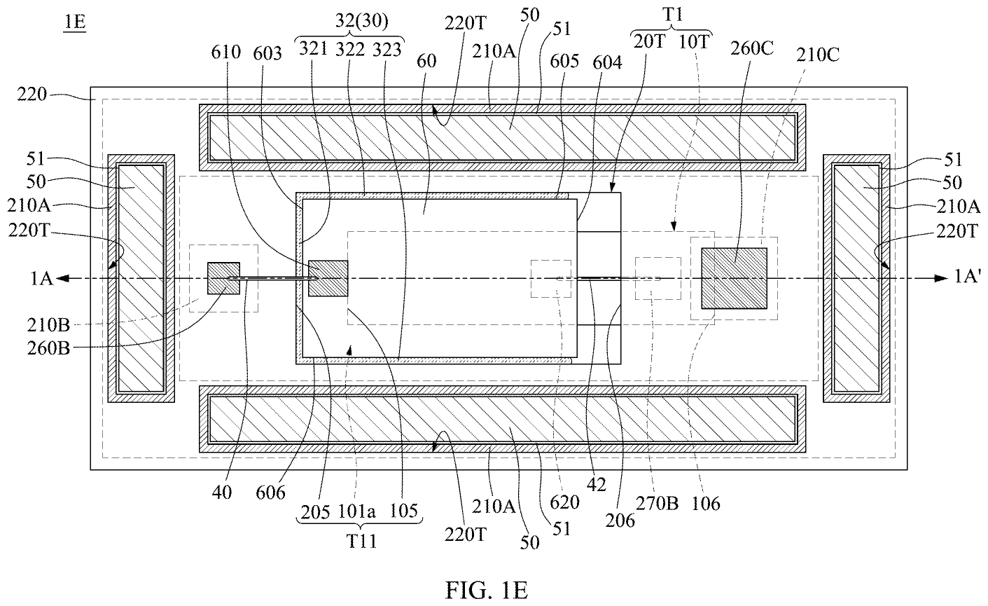

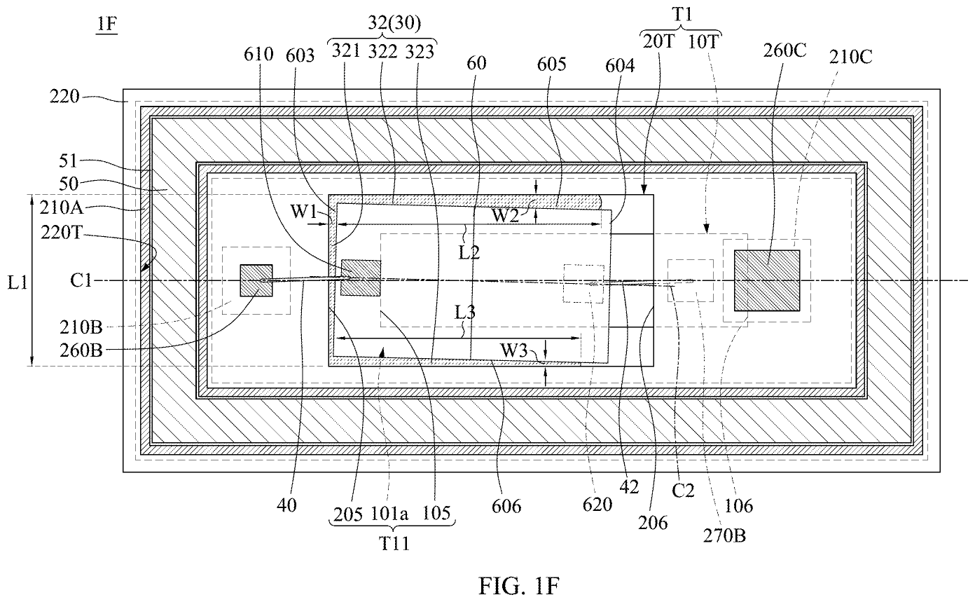

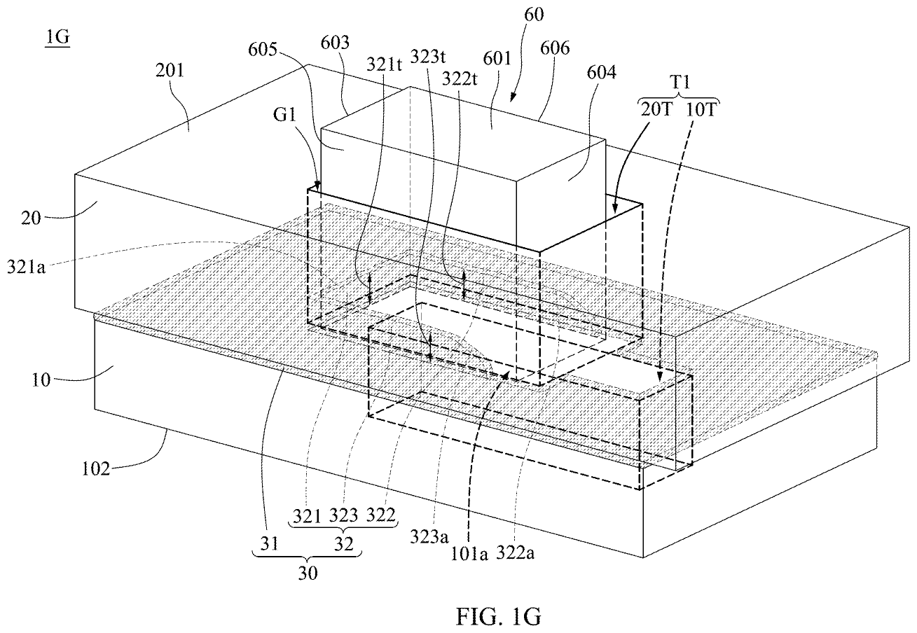

FIG. 1A is a cross-section of a package structure 1A in accordance with some arrangements of the present disclosure. The package structure 1A may include substrates 10 and 20, an adhesive layer 30, conductive wires 40 and 42, a spacer structure 50, an adhesive element 51, a chip 60, and connection elements 90.

The substrates 10 and 20 may independently include, for example, a printed circuit board, such as a paper-based copper foil laminate, a composite copper foil laminate, or a polymer-impregnated glass-fiber-based copper foil laminate. The substrates 10 and 20 may independently include an interconnection structure, which may include a plurality of conductive traces and/or conductive vias. The interconnection structure may include a redistribution layer (RDL) and/or a grounding element. In some arrangements, the substrates 10 and 20 may independently include an organic substrate or a leadframe. In some arrangements, the substrates 10 and 20 may independently include a ceramic material or a metal plate. In some arrangements, the substrates 10 and 20 may independently include a two-layer substrate which includes a core layer and a conductive material and/or structure disposed on an upper surface and a bottom surface of the substrate. The substrates 10 and 20 may independently include a semiconductor wafer or an electronic component. The electronic component may be a chip or a die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the substrates 10 and 20 may independently include one or more conductive elements, surfaces, contacts, or pads.

In some arrangements, the substrate 10 has a surface 101 (also referred to as “a top surface” or “an upper surface”) and a surface 102 (also referred to as “a bottom surface” or “a lower surface”) opposite to the surface 101. In some arrangements, the substrate 10 defines a through hole 10T. In some arrangements, the through hole 10T extends between the surface 101 (or the top surface) and the surface 102 (or the bottom surface) of the substrate 10. In some arrangements, the through hole 10T includes at least sidewalls 105 and 106 in a cross-sectional view perspective. The substrate 10 may be referred to as a first substrate or a lower substrate. The through hole 10T may be referred to as a lower through hole.

In some arrangements, the substrate 10 includes a base layer 100, circuit layers 110 and 130, dielectric layers 120 and 140, and one or more conductive vias 150. In some arrangements, the base layer 100 may be or include a semiconductor substrate or other suitable materials or elements included in the substrate 10 as described above. In some arrangements, the circuit layer 110 is adjacent to the surface 101 (or the top surface), and the circuit layer 130 is adjacent to the surface 102 (or the bottom surface). In some arrangements, the circuit layer 110 may be or include conductive pads, conductive layers, conductive patterns, conductive portions, or the like. In some arrangements, the circuit layer 110 includes portions 110A and 110B. The portions 110A and 110B may be electrically disconnected from each other. In some arrangements, the circuit layer 130 may be or include conductive pads, conductive layers, conductive patterns, conductive portions, or the like. In some arrangements, the circuit layer 130 includes portions 130A and 130B. The portions 130A and 130B may be electrically disconnected from each other. In some arrangements, the circuit layer 130 further includes a protective film 170B on the portion 130B. The protective film may be or include a metal finish layer, such as NiAu alloy or other suitable materials.

In some arrangements, the dielectric layers 120 and 140 are disposed on the circuit layers 110 and 130, respectively. In some arrangements, the dielectric layer 120 has one or more openings exposing portions of the circuit layer 110. In some arrangements, the dielectric layer 140 has one or more openings 140T exposing portions of the circuit layer 130. In some arrangements, the protective film 170B is exposed by the openings 140T. In some arrangements, the conductive via 150 electrically connects the surface 101 to the surface 102 of the substrate 10. In some arrangements, the conductive vias 150 penetrate the base layer 100. In some arrangements, the conductive via 150 includes a conductive liner 151 and an insulative filling layer 153 (e.g., a dielectric layer). In some arrangements, one of the conductive vias 150 is electrically connected to the portion 110A of the circuit layer 110 and the portion 130A of the circuit layer 130, and another one of the conductive vias 150 is electrically connected to the portion 110B of the circuit layer 110 and the portion 130B of the circuit layer 130.

The substrate 20 may be disposed over the substrate 10. In some arrangements, the substrate 20 is physically spaced apart from the substrate 10. In some arrangements, the substrate 20 has a surface 201 (also referred to as “a top surface” or “an upper surface”) and a surface 202 (also referred to as “a bottom surface” or “a lower surface”) opposite to the surface 201. In some arrangements, the substrate 20 defines a through hole 20T. In some arrangements, the through hole 20T extends between the surface 201 (or the top surface) and the surface 202 (or the bottom surface) of the substrate 20. In some arrangements, the through hole 20T includes at least sidewalls 205 and 206 in a cross-sectional view perspective. The substrate 20 may be referred to as a second substrate or an upper substrate. The through hole 20T may be referred to as an upper through hole. In some arrangements, a thickness 20t of the substrate 20 is greater than a thickness 10t of the substrate 10. In some arrangements, a ratio (10t/20t) of the thickness 10t with respect to the thickness 20t may be less than about 0.5. In some arrangements, the ratio (10t/20t) of the thickness 10t with respect to the thickness 20t is from about 0.1 to about 0.5, for example, about 0.25. In some arrangements, a center axis C10T of the through hole 10T is misaligned with a center axis C20T of the through hole 20T in a cross-sectional view perspective.

In some arrangements, the substrate 20 includes a base layer 200, circuit layers 210 and 230, dielectric layers 220 and 240, and one or more conductive vias 250. In some arrangements, the base layer 200 may be or include a semiconductor substrate or other suitable materials or elements included in the substrate 20 as described above. In some arrangements, the circuit layer 210 is adjacent to the surface 201 (or the top surface), and the circuit layer 230 is adjacent to the surface 202 (or the bottom surface). In some arrangements, the circuit layer 210 may be or include conductive pads, conductive layers, conductive patterns, conductive portions, or the like. In some arrangements, the circuit layer 210 includes portions 210A, 210B, and 210C. The portions 210A, 210B, and 210C may be electrically disconnected from one another. In some arrangements, the circuit layer 210 further includes protective films 260B and 260C on the portions 210B and 210C, respectively. The portions 210A, 210B, and 210C and the protective films 260B and 260C may be referred to as pads or conductive pads. The protective film may be or include a metal finish layer, such as NiAu alloy or other suitable materials. In some arrangements, the circuit layer 230 may be or include conductive pads, conductive layers, conductive patterns, conductive portions, or the like. In some arrangements, the circuit layer 230 includes portions 230A, 230B, and 230C. The portions 230A, 230B, and 230C may be electrically disconnected from one another. In some arrangements, the circuit layer 230 further includes a protective film 270B on the portions 230B. The protective film may be or include a metal finish layer, such as NiAu alloy or other suitable materials. The portions 230A, 230B, and 230C and the protective film 270B may be referred to as pads or conductive pads. In some arrangements, the portion 230B and the protective film 270B are exposed by the through hole 10T.

In some arrangements, the dielectric layers 220 and 240 are disposed on the circuit layers 210 and 230, respectively. In some arrangements, the dielectric layer 220 has one or more openings 220T exposing portions of the circuit layer 210. In some arrangements, the dielectric layer 240 has one or more openings exposing portions of the circuit layer 230. In some arrangements, the protective films 260B and 260C are exposed by the openings 220T. In some arrangements, the conductive via 250 electrically connects the surface 201 to the surface 202 of the substrate 20. In some arrangements, the conductive vias 250 penetrate the base layer 200. In some arrangements, the conductive via 250 includes a conductive liner 251 and an insulative filling layer 253 (e.g., a dielectric layer). In some arrangements, one of the conductive vias 250 is electrically connected to the portion 210A of the circuit layer 210 and the portion 230A of the circuit layer 230, and another one of the conductive vias 150 is electrically connected to the portion 210B of the circuit layer 210 and the portion 230C of the circuit layer 230. In some arrangements, the conductive vias 150 and 250 may collectively construct a conductive via structure that electrically connects the substrate 10 to the substrate 20.

The chip 60 may be disposed in the through hole 20T of the substrate 20. In some arrangements, the chip 60 has a surface 601 (also referred to as “a top surface” or “an upper surface”), a surface 602 (also referred to as “a bottom surface” or “a lower surface”) opposite to the surface 601, and at least surfaces 603 and 604 (also referred to as “lateral side surfaces”) extending between the surface 601 and the surface 602. In some arrangements, the surface 601 (or the top surface) of the chip 60 is protruded beyond the surface 201 (or the top surface) of the substrate 20, and the surface 602 (or the bottom surface) of the chip 60 is substantially aligned with the surface 101 (or the top surface) of the substrate 10. In some arrangements, an elevation of the surface 602 (or the bottom surface) of the chip 60 is lower than the surface 202 (or the bottom surface) of the substrate 20 with respect to the surface 101 (or the top surface) of the substrate 10. In some arrangements, the surface 601 of the chip 60 and the surface 201 of the substrate 20 are at different elevations. The chip 60 may be or include a sensor. The sensor may be or include a micro-electromechanical system (MEMS) sensor, a temperature sensor, a pressure sensor, a humidity sensor, an inertial force sensor, a chemical species sensor, a magnetic field sensor, or a combination thereof.

In some arrangements, the surface 603 (or the lateral side surface) of the chip 60 is separated from or spaced apart from the sidewall 205 of the through hole 20T by a gap G1. In some arrangements, the surface 604 (or the lateral side surface) of the chip 60 is separated from or spaced apart from the sidewall 206 of the through hole 20T by a gap G3. In some arrangements, the gap G3 may be greater or wider than the gap G1. In some arrangements, a ratio (G3w/20t) of a width G3w of the gap G3 with respect to the thickness 20t of the substrate 20 is from about 0.2 to about 0.5, for example, about 0.3. In some arrangements, a width G1w of the gap G1 is about 50 μm. In some arrangements, the width G3w of the gap G3 is from about 100 μm to about 500 μm or from about 200 μm to about 300 μm. In some arrangements, the thickness 20t of the substrate 20 is from about 800 μm to about 1200 μm. In some arrangements, a thickness of the chip 60 is greater than a thickness of the substrate 20. In some arrangements, a thickness of the chip 60 is greater than a depth of the through hole 20T.

In some arrangements, the chip 60 includes a sensing element 601S adjacent to the surface 601 and a sensing element 602S adjacent to the surface 602. In some arrangements, the sensing element 601S is exposed by the surface 601 of the chip 60, and the sensing element 602S is exposed by the surface 602 of the chip 60. In some arrangements, the sensing elements 601S and 602S are exposed by the substrate 20. In some arrangements, the chip 60 includes a sensing surface 601S1 and a sensing surface 602S1 opposite to the sensing surface 601S1. The sensing element 601S may include the sensing surface 601S1, and the sensing element 602S may include the sensing surface 602S1. In some arrangements, the sensing surface 602S1 of the sensing element 602S is substantially aligned with the surface 101 of the substrate 10. The surface 601 and the surface 602 may be referred to as active surfaces of the chip 60. The term “active surface” used herein refers to a surface with one or more pads or terminals that may connect to one or more external elements. For example, the surfaces 601 and 602 with the pads 610 and 620 may be active surfaces of the chip 60. The term “active surface” used herein also refers to a surface that is configured to perform an active function, e.g., a sensing function. For example, the surfaces 601 and 602 including the sensing surfaces 601S1 and 602S1 may be active surfaces of the chip 60. In some arrangements, the surface 602 (or the active surface) of the chip 60 is substantially aligned with the surface 101 of the substrate 10. In some arrangements, the surface 602 (or the bottom surface) of the chip 60 is protruded beyond the surface 202 (or the bottom surface) of the substrate 20.

In some arrangements, the chip 60 includes at least pads 610 and 620 (also referred to as “conductive pads” or “conductive terminals”). In some arrangements, the pad 610 is on or adjacent to the surface 601 (or the top surface) of the chip 60, and the pad 620 is on or adjacent to the surface 602 (or the bottom surface) of the chip 60. In some arrangements, the pad 610 is protruded beyond the surface 601 of the chip 60, and the pad 620 is protruded beyond the surface 602 of the chip 60. In some arrangements, the pad 620 is at an opposite side of the chip 60 to the pad 610. In some arrangements, the pad 610 is electrically connected to the surface 201 of the substrate 20, and the pad 620 is electrically connected to the surface 202 of the substrate 20.

The adhesive layer 30 may be disposed between the substrate 10 and the substrate 20. In some arrangements, the adhesive layer 30 connects the substrate 10 and the substrate 20. In some arrangements, the adhesive layer 30 covers or contacts a portion of one or more lateral side surfaces (e.g., the surface 603) of the chip 60. In some arrangements, the adhesive layer 30 further covers or contacts a portion of the sidewall 205 of the through hole 20T. In some arrangements, the adhesive layer 30 further covers or contacts a portion of the sidewall 105 of the through hole 10T. In some arrangements, the adhesive layer 30 may be or include an encapsulant or an underfill. The encapsulant or the underfill may include an epoxy resin, a molding compound (e.g., an epoxy molding compound or other molding compound), polyimide, a phenolic compound or material, a material including a silicone dispersed therein, or a combination thereof.

In some arrangements, the substrate 10 and the substrate 20 collectively construct a substrate structure. In some arrangements, the substrate structure defines a through hole T1. In some arrangements, the substrate 10 and the substrate 20 collectively define the through hole T1. In some arrangements, the through hole 20T of the substrate 20 partially overlaps the through hole 10T of the substrate 10 to define the through hole T1 of the substrate structure.

In some arrangements, the through hole T1 of the substrate structure includes a stepped sidewall structure T11 (also referred to as “a stepped structure”). In some arrangements, the substrates 10 and 20 collectively define the stepped sidewall structure T11 (or the stepped structure). In some arrangements, a portion 101a of the surface 101 of the substrate 10 is exposed by the through hole 20T of the substrate 20. In some arrangements, the dielectric layer 120 defines a step surface (e.g., the portion 101a of the surface 101) of the stepped sidewall structure T11. In some arrangements, the stepped sidewall structure T11 includes a first vertical sidewall (e.g., the sidewall 205 of the through hole 20T), a second vertical sidewall (e.g., the sidewall 105 of the through hole 10T) misaligned with the first vertical sidewall, and a horizontal intermediate surface (e.g., the portion 101a of the surface 101). In some arrangements, the horizontal intermediate surface (e.g., the portion 101a of the surface 101) is connected to the second vertical sidewall (e.g., the sidewall 105), and the first vertical sidewall (e.g., the sidewall 205) is disconnected from the horizontal intermediate surface (e.g., the portion 101a of the surface 101) by a gap G2. In some arrangements, the substrate 10 and the substrate 20 are separated by the gap G2. The portion 101a of the surface 101 (or the horizontal intermediate surface of the stepped sidewall structure T11) may serve as a supporting platform for the chip 60 to be disposed thereon. In some arrangements, a ratio (101aw/20Tw) of a width 101aw of the portion 101a with respect to a width 20Tw of the through hole 20T may be equal to or greater than about 0.15, for example, from about 0.15 to about 0.3 or from about 0.17 to about 0.2. In some arrangements, the width 101aw is from about 300 μm to about 400 μm.

In some arrangements, the adhesive layer 30 covers a portion of the stepped sidewall structure T11. In some arrangements, the adhesive layer 30 covers a portion of the sidewall 205 (or the lateral surface) of the stepped sidewall structure T11. In some arrangements, the adhesive layer 30 connects the chip 60 to the stepped sidewall structure T11. In some arrangements, the adhesive layer 30 contacts the first vertical sidewall (e.g., the sidewall 205) and extends into the gap G2. In some arrangements, the adhesive layer 30 includes at least portions 31, 32, and 33. In some arrangements, the portion 31 of the adhesive layer 30 is embedded in the substrate structure. In some arrangements, the portion 31 is filled in the gap G2 between the substrate 10 and the substrate 20. In some arrangements, the adhesive layer 30 covers a portion of the surface 603 (or a lateral surface) of the chip 60. In some arrangements, the portion 31 horizontally overlaps the chip 60. In some arrangements, the portion 32 of the adhesive layer 30 contacts the chip 60. In some arrangements, the portion 32 of the adhesive layer 30 is at least partially filled in the gap G1 between the sidewall 205 of the through hole 20T and the surface 603 of the chip 60. In some arrangements, a thickness of the portion 32 may be equal to or less than about half the depth of the gap G1. In some arrangements, a ratio of the thickness of the portion 32 with respect to the depth of the gap G1 may be equal to or less than about 0.5, for example, about 0.3 or less. In some arrangements, the portion 33 of the adhesive layer 30 covers or contacts a portion of the sidewall 105 of the through hole 10T.

In some arrangements, the chip 60 is disposed in the through hole T1 and supported by the stepped sidewall structure T11. In some arrangements, the chip 60 is disposed on the stepped sidewall structure T11 in the through hole T1. In some arrangements, the chip 60 directly contacts the step surface (e.g., the portion 101a of the surface 101) of the stepped sidewall structure T11. In some arrangements, the chip 60 is at least partially accommodated by the through hole 20T and supported by the portion 101a of the surface 101 of the substrate 10 (e.g., the dielectric layer 120). In some arrangements, the chip 60 is disposed on the portion 101a of the surface 101 of the substrate 10 (e.g., the dielectric layer 120). In some arrangements, the chip 60 directly contacts the step surface (e.g., the portion 101a of the surface 101) of the dielectric layer 120. In some arrangements, the dielectric layer 120 includes a solder mask layer.

The conductive wire 40 may connect the chip 60 to the substrate 20. In some arrangements, the chip 60 is electrically connected to the substrate 20 through the conductive wire 40. In some arrangements, the conductive wire 40 electrically connects the surface 601 of the chip 60 to the surface 201 of the substrate 20. In some arrangements, the pad 610 of the chip 60 is electrically connected to the surface 201 of the substrate 20 by the conductive wire 40. In some arrangements, the conductive wire 40 electrically connects the pad 610 of the chip 60 to the protective film 260B and the portion 210B of the circuit layer 210 of the substrate 20.

The conductive wire 42 may connect the chip 60 to the substrate 20. In some arrangements, the chip 60 is electrically connected to the substrate 20 through the conductive wire 42. In some arrangements, the conductive wire 42 electrically connects the surface 602 of the chip 60 to the surface 202 of the substrate 20. In some arrangements, the pad 620 of the chip 60 is electrically connected to the surface 202 of the substrate 20 by the conductive wire 42. In some arrangements, the conductive wire 42 electrically connects the pad 620 of the chip 60 to the protective film 270B and the portion 230B of the circuit layer 230 of the substrate 20. In some arrangements, the conductive wire 42 is received within the through hole 10T of the substrate 10. In some arrangements, a distance between the substrate 20 and the surface 102 of the substrate 10 is greater than a distance between the substrate 20 and a bottom end (also referred to as “a bottom apex”) 421 of the conductive wire 42. In some arrangements, a curvature of the conductive wire 40 is greater than a curvature of the conductive wire 42. In some arrangements, a curvature change of the conductive wire 40 is greater than a curvature change of the conductive wire 42. The term “curvature change” used herein may indicate a change in heights or elevations of the conductive wire within a predetermined horizontal distance. The term “curvature change” may also reflect the slope of the conductive wire.

The spacer structure 50 may be disposed around the conductive wire 40. In some arrangements, an elevation of a top surface 501 of the spacer structure 50 is higher than an elevation of a top end (also referred to as “a top apex”) 401 of the conductive wire 40 with respect to the surface 201 of the substrate 20. In some arrangements, the spacer structure 50 is disposed on the surface 201 of the substrate 20 and configured to protect the chip 60 from being damaged. In some arrangements, the spacer structure 50 is disposed on the surface 201 of the substrate 20 and defines a space S1 for accommodating the conductive wire 40 and a portion of the chip 60 protruded beyond the surface 201 of the substrate 20. In some arrangements, the spacer structure 50 is connected to (or electrically connected to) ground through the conductive via 250. The spacer structure 50 may be referred to as a protective element. The protective element may be disposed on the surface 201 of the substrate 20 and surrounding the chip 60. The protective element on the surface 202 of the substrate is configured to prevent the chip 60 from impacts from outside of the protective element. The spacer structure 50 may serve as a shielding element configured to reduce electromagnetic interference (EMI). In some arrangements, the spacer structure 50 may be referred to as or include a spacer, a metal spacer, an interposer, or the like. The spacer structure 50 may be or include a metal frame or a metal wall structure. In some embodiments, the spacer structure 50 is made of or include a conductive material including, for example, aluminum (Al), copper (Cu), chromium (Cr), tin (Sn), gold (Au), silver (Ag), nickel (Ni) or stainless steel, or a mixture, an alloy, or other combination thereof.

The adhesive element 51 may connect the spacer structure 50 to the substrate 20. In some arrangements, the adhesive element 51 is at least partially within the opening 220T of the dielectric layer 220. In some arrangements, the adhesive element 51 is formed of or includes a conductive material. The adhesive element 51 may be or include a conductive adhesive, e.g., a silver paste or a silver gel. The adhesive element 51 may be or include a solder material. In some arrangements, the adhesive element 51 electrically connects the spacer structure 50 to the portion 210A of the circuit layer 210.

The connection elements 90 may be between the substrate 10 and the substrate 20. In some arrangements, the connection elements 90 electrically connect the circuit layer 110 of the substrate 10 to the circuit layer 230 of the substrate 20. In some arrangements, the portion 31 of the adhesive layer 30 encapsulates the connection elements 90. In some arrangements, the conductive wire 42 horizontally overlaps the connection elements 90. In some arrangements, the connection elements 90 may be or include conductive bumps. The conductive bumps may be or include gold (Au), silver (Ag), copper (Cu), another metal, a solder alloy, or a combination of two or more thereof.

The conductive layers, pads, pillars, portions, vias, liners, and/or terminals may independently include a conductive material such as a metal or metal alloy. Examples include Au, Ag, Al, Cu, or an alloy thereof. The dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

FIG. 1B is a cross-section of a package structure 1B in accordance with some arrangements of the present disclosure. The package structure 1B illustrated in FIG. 1B is similar to that in FIG. 1A, with differences therebetween as follows.

In some arrangements, the adhesive layer 30 is free from covering or contacting the sidewall 105 of the through hole 10T of the substrate 10. In some arrangements, the adhesive layer 30 does not include a portion covering or contacting a portion of the sidewall 105 of the through hole 10T.

FIG. 1C is a cross-section of a package structure 1C in accordance with some arrangements of the present disclosure. The package structure 1C illustrated in FIG. 1C is similar to that in FIG. 1A, with differences therebetween as follows.

In some arrangements, the spacer structure 50 is adhered to the dielectric layer 220 of the substrate 20 through the adhesive element 51. In some arrangements, the adhesive element 51 is or includes an insulating adhesive material. In some arrangements, the spacer structure 50 may include a dielectric material, a conductive material, or any suitable spacer materials. In some arrangements, the spacer structure 50 is not electrically connected to ground or any conductive structure.

FIG. 1D is a top view of a package structure 1D in accordance with some arrangements of the present disclosure. In some arrangements, FIG. 1D shows a top view of the package structure 1A illustrated in FIG. 1A, the package structure 1B illustrated in FIG. 1B, or the package structure 1C illustrated in FIG. 1C. In some arrangements, FIG. 1A, FIG. 1B, or FIG. 1C shows a cross-section along a line 1A-1A′ in FIG. 1D.

The chip 60 may have surfaces 603, 604, 605, and 606 (also referred to as “lateral side surfaces”). In some arrangements, the surfaces 605 and 606 are adjacent to the surface 603, and the surface 604 is opposite to the surface 603. In some arrangements, the adhesive layer 30 covers at least a portion of the surface 603 of the chip 60 and a portion of the surface 605 of the chip 60. In some arrangements, the adhesive layer 30 covers at least a portion of the surface 603 of the chip 60 and a portion of the surface 606 of the chip 60. In some arrangements, the adhesive layer 30 covers at least a portion of the surface 603 of the chip 60, a portion of the surface 605 of the chip 60, and a portion of the surface 606 of the chip 60. In some arrangements, the adhesive layer 30 is spaced apart from the surface 604 of the chip 60.

In some arrangements, the portion 32 of the adhesive layer 30 includes portions 321, 322, and 323. The portions 321, 322, and 323 may be referred to as sub-portions or parts of the portion 32 of the adhesive layer 30. In some arrangements, the portion 321 contacts the surface 603 (or the lateral side surface) of the chip 60, the portion 322 contacts the surface 605 (or the lateral side surface) of the chip 60, and the portion 323 contacts the surface 606 (or the lateral side surface) of the chip 60.

In some arrangements, at least two or more of the portions 321, 322, and 323 of the adhesive layer 30 have different widths. For example, a width W1 of the portion 321 may be less than a width W2 of the portion 322. For example, a width W3 of the portion 323 may be less than the width W2 of the portion 322. For example, the width W1 of the portion 321 may be different from the width W3 of the portion 323.

In some arrangements, at least two or more of the portions 321, 322, and 323 of the adhesive layer 30 have different lengths. For example, a length L1 of the portion 321 may be less than a length L2 of the portion 322. For example, a length L3 of the portion 323 may be less than the length L2 of the portion 322. For example, the length L1 of the portion 321 may be less than the length L3 of the portion 323.

In some arrangements, the portion 210A of the circuit layer 210 surrounds the chip 60, the adhesive layer 30, and the through hole T1. In some arrangements, the opening 220T of the dielectric layer 220 surrounds the chip 60, the adhesive layer 30, and the through hole T1. In some arrangements, the portion 210A is partially exposed by the opening 220T. In some arrangements, the spacer structure 50 surrounds the chip 60, the adhesive layer 30, and the through hole T1. In some arrangements, the adhesive element 51 surrounds the chip 60, the adhesive layer 30, and the through hole T1.

FIG. 1E is a top view of a package structure 1E in accordance with some arrangements of the present disclosure. In some arrangements, FIG. 1E shows a top view of the package structure 1A illustrated in FIG. 1A, the package structure 1B illustrated in FIG. 1B, or the package structure 1C illustrated in FIG. 1C. In some arrangements, FIG. 1A, FIG. 1B, or FIG. 1C shows a cross-section along a line 1A-1A′ in FIG. 1E. The package structure 1E illustrated in FIG. 1E is similar to that in FIG. 1D, with differences therebetween as follows.

In some arrangements, the portion 210A of the circuit layer 210 surrounds the chip 60, the adhesive layer 30, and the through hole T1. In some arrangements, the dielectric layer 220 has multiple openings 220T adjacent to the surfaces 603, 604, 605, and 606 of the chip 60, respectively. In some arrangements, the portion 210A includes multiple segments partially exposed by the multiple openings 220T, respectively. In some arrangements, the spacer structure 50 includes multiple segments disposed on the respective exposed segments of the portion 210A. In some arrangements, the adhesive element 51 includes multiple segments connecting the segments of the spacer structure 50 to the respective exposed segments of the portion 210A.

FIG. 1F is a top view of a package structure 1F in accordance with some arrangements of the present disclosure. In some arrangements, FIG. 1F shows a top view of the package structure 1A illustrated in FIG. 1A, the package structure 1B illustrated in FIG. 1B, or the package structure 1C illustrated in FIG. 1C. In some arrangements, FIG. 1A, FIG. 1B, or FIG. 1C shows a cross-section along a line 1A-1A′ in FIG. 1F. The package structure 1F illustrated in FIG. 1F is similar to that in FIG. 1E, with differences therebetween as follows.

In some arrangements, in a top view perspective, a center axis C1 of the substrate structure (e.g., the substrates 10 and 20) is non-parallel to a center axis C2 of the chip 60.

In some arrangements, in a top view perspective, the adhesive layer 30 is between a sidewall of the substrate structure (e.g., the substrates 10 and 20) and the surfaces 603, 605, and 606 (also referred to as side surfaces) of the chip 60. In some arrangements, in a top view perspective, the adhesive layer 30 includes a portion 322 adjacent to the surface 605 and a portion 323 adjacent to the surface 606, and the portions 322 and 323 have different lengths (e.g., the lengths L2 and L3). In some arrangements, in a top view perspective, the portion 322 of the adhesive layer 30 has a non-uniform width W2.

In some arrangements, the conductive wire 40 connects the chip 60 to the substrate structure (e.g., the substrates 10 and 20), and in a top view perspective, an extending direction of the conductive wire 40 is non-parallel to the center axis C1 of the substrate structure.

FIG. 1G is a perspective view of a package structure 1G in accordance with some arrangements of the present disclosure. In some arrangements, FIG. 1G shows a perspective view of the package structure 1A illustrated in FIG. 1A, the package structure 1B illustrated in FIG. 1B, or the package structure 1C illustrated in FIG. 1C. Please be noted that some elements are omitted in FIG. 1G for clarity. For example, the connection elements 90 encapsulated by the adhesive layer 30, the conductive elements and the dielectric layers of the substrates 10 and 20, the pads of the chip 60 are omitted, the conductive wires 40 and 42, and the spacer structure 50 are omitted, such that the structural relationship between the adhesive layer 30, the chip 60, and the substrate structure (e.g., the substrates 10 and 20 and the through holes 10T and 20T) can be represented clearly.

The portion 101a of the surface 101 exposed by the through hole 20T may serve as a supporting platform for the chip 60 to be disposed thereon. In some arrangements, the portion 101a has an U-shape profile from a top view perspective. In some arrangements, the portion 31 of the adhesive layer 30 surrounds the chip 60. In some arrangements, the portion 32 of the adhesive layer 30 has a non-uniform thickness.

In some arrangements, an elevation of a top surface of the portion 32 of the adhesive layer 30 is between a top surface (e.g., the surface 201) of the substrate structure and a bottom surface (e.g., the surface 102) of the substrate structure. In some arrangements, an elevation of a top surface (e.g., the surface 601) of the chip 60 is lower than the elevation of the top surface of the portion 32 of the adhesive layer 30 with respect to the bottom surface (e.g., the surface 102) of the substrate structure.

In some arrangements, an elevation of a top surface 321a of the portion 321, an elevation of a top surface 322a of the portion 322, and an elevation of a top surface 323a of the portion 323 may be between a top surface (e.g., the surface 201) of the substrate structure and a bottom surface (e.g., the surface 102) of the substrate structure. In some arrangements, an elevation of a top surface (e.g., the surface 601) of the chip 60 is lower than the elevations of the top surface 321a of the portion 321, the top surface 322a of the portion 322, and the top surface 323a of the portion 323 with respect to the bottom surface (e.g., the surface 102) of the substrate structure. In some arrangements, the top surfaces 321a, 322a and 323a are non-planar surfaces.

In some arrangements, two or more of the portions 321, 322, and 323 of the adhesive layer 30 have different thicknesses. In some arrangements, a thickness 321t of the portion 321 may be substantially equal to or greater than a thickness 322t of the portion 322. In some arrangements, a thickness 321t of the portion 321 may be substantially equal to or greater than a thickness 323t of the portion 323. In some arrangements, a thickness 322t of the portion 322 decreases toward a direction away from the portion 321. In some arrangements, a thickness 323t of the portion 323 decreases toward a direction away from the portion 321.

In some cases where a ceramic substrate is manufactured to provide a specific structure for a chip to be disposed therein, such that the I/O terminals on opposite sides of the chip can be exposed by the ceramic substrate for electrical connection. However, the cost and the difficulty for manufacturing the ceramic substrate with the specific structure may be relatively high, and the brittle texture of the ceramic substrate may render the ceramic substrate relatively fragile and thus reducing the yield. To solve the above problems, a plastic substrate including a specific structure to the chip to be disposed therein may be provided. The plastic substrate may be formed by the following steps: a top cavity and a bottom cavity may be formed from the top surface and the bottom surface of the plastic substrate, respectively, to connect the top cavity and the bottom cavity to form a through hole with a platform defined by the cavities in the plastic substrate, such that the chip may be disposed on the platform in the through hole of the plastic substrate. However, it is relatively difficult to precisely control the depths of the top cavity and the bottom cavity during the two-step cavity-forming process, and thus the variations in depths of the cavities may render the as-formed platform to have a non-uniform elevation or surface profile, which may reduce the yield as well.

According to some arrangements of the present disclosure, two substrates each having a through hole are stacked over each other to form a combined through hole with an exposed portion of a top surface of the lower substrate serving as a platform for supporting the chip. The process for forming the through holes of the substrates is relatively easy and simplified (e.g., by one-step drilling operations), the issue of difficulty in controlling the depths of multiple cavities can be omitted, thus the yield can be increased, and the cost can be reduced. Furthermore, the platform formed by an exposed portion of a top surface of the lower substrate may have a relatively uniform elevation or a relatively flat surface profile, and thus the chip can be prevented from being inclined, and thus the alignment accuracy of connecting the conductive wires to the bonding areas (e.g., the pads) of the chip can be improved, thus the positional offset errors can be reduced, and the yield can be further increased. In addition, both sides or surfaces of the chip can be exposed by opposite openings of the combined through hole, such that both sides or surfaces of the chip can be electrically connected to conductive elements (e.g., conductive wires).

In addition, according to some arrangements of the present disclosure, the adhesive layer encapsulates the connection elements between the substrates and covers portions of the lateral side surfaces of the chip. As such, the connection elements that can electrically connect the substrates and configured to transmit signals between the substrates can be protected by the adhesive layer, and the adhesion between the chip and the sidewall of the through hole can be improved. Therefore, the reliability of the package structure can be increased, and the yield can be increased as well.

Moreover, according to some arrangements of the present disclosure, the spacer structure is taller than the chip and the conductive wire over the top surface of the substrate, such that the spacer structure can protect the chip and the conductive wire from being damaged. In addition, the spacer structure may be further electrically connected to ground, such that the spacer structure can further serve as an EMI shielding element for the chip without disposing or installing additional EMI shielding structures. Therefore, the electrical performance of the package structure can be improved without increasing the package size.

In addition, according to some arrangements of the present disclosure, the conductive wire is received within a through hole of one of the substrates. Therefore, the conductive wire can be protected from being damaged without encapsulating the conductive wire by a protective element.

Furthermore, according to some arrangements of the present disclosure, the gap between the chip and the sidewall of the through hole is relatively small (e.g., a ratio (G3w/20t) of a width G3w of the gap G3 with respect to the thickness 20t of the substrate 20 is from about 0.2 to about 0.5, for example, about 0.3.). As such, the gap with the specific dimension design is large enough provide a tolerance space for disposing the chip into the through hole without accidentally hitting or rubbing against the sidewall of the through hole, and the gap is also small enough to prevent impurities or particles from falling into the through hole. Therefore, the chip can be prevented from being damaged, and the impurities or particles can be avoided as well.

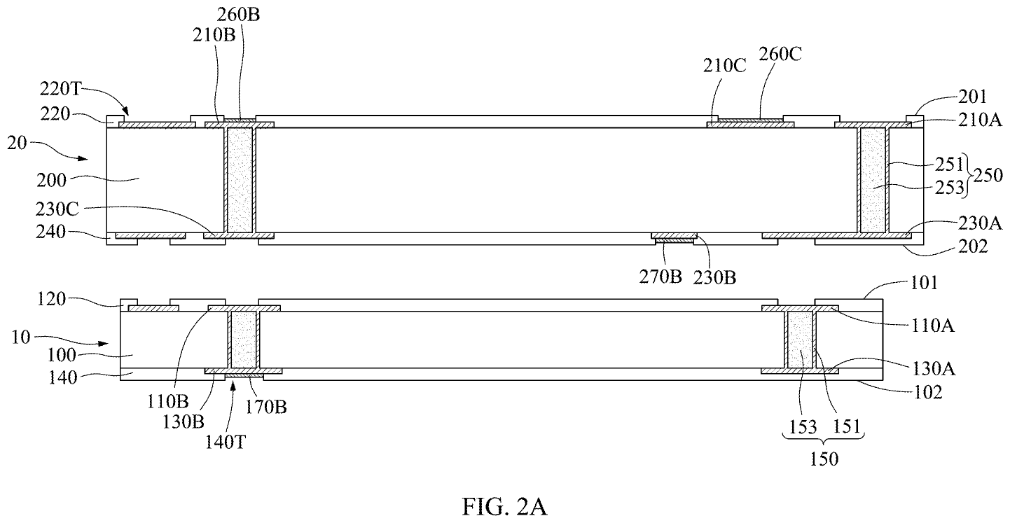

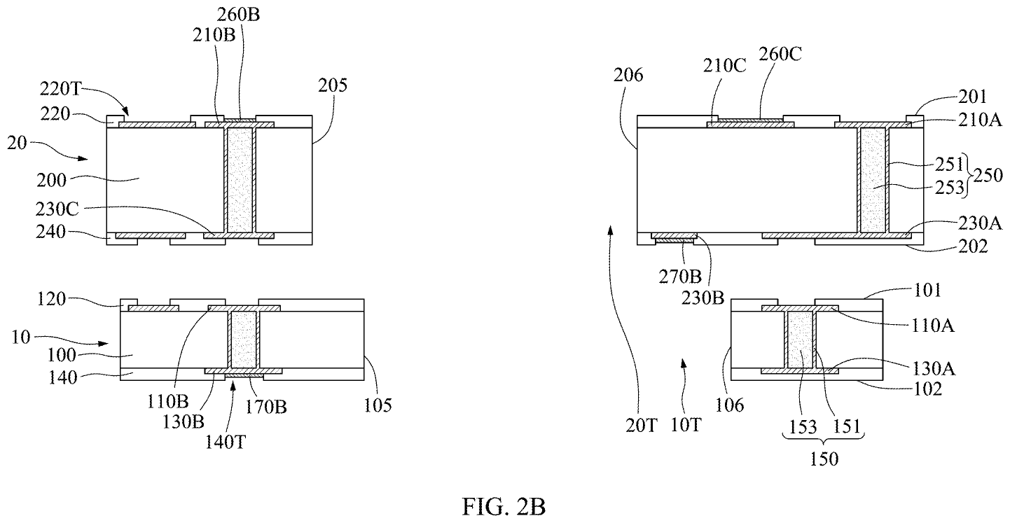

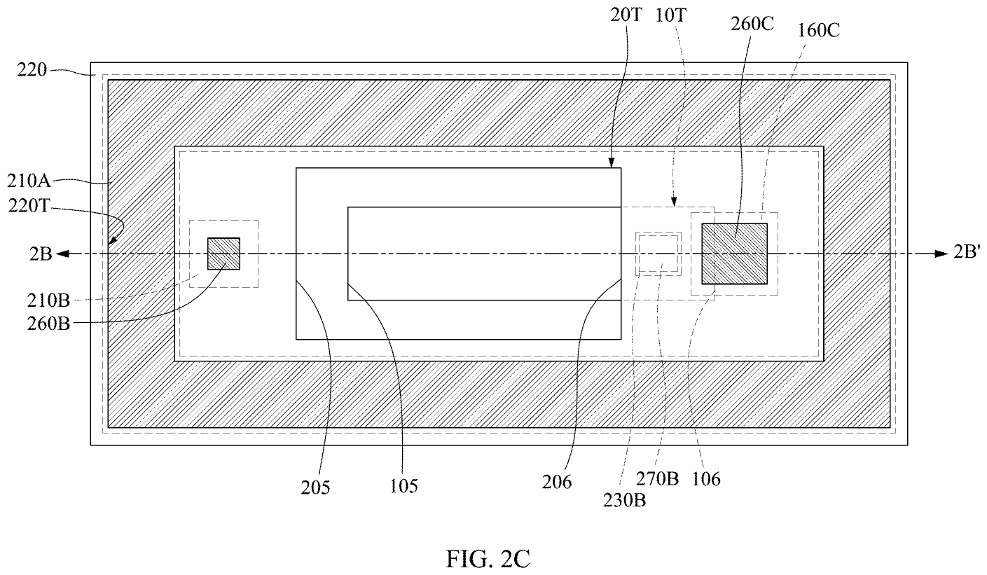

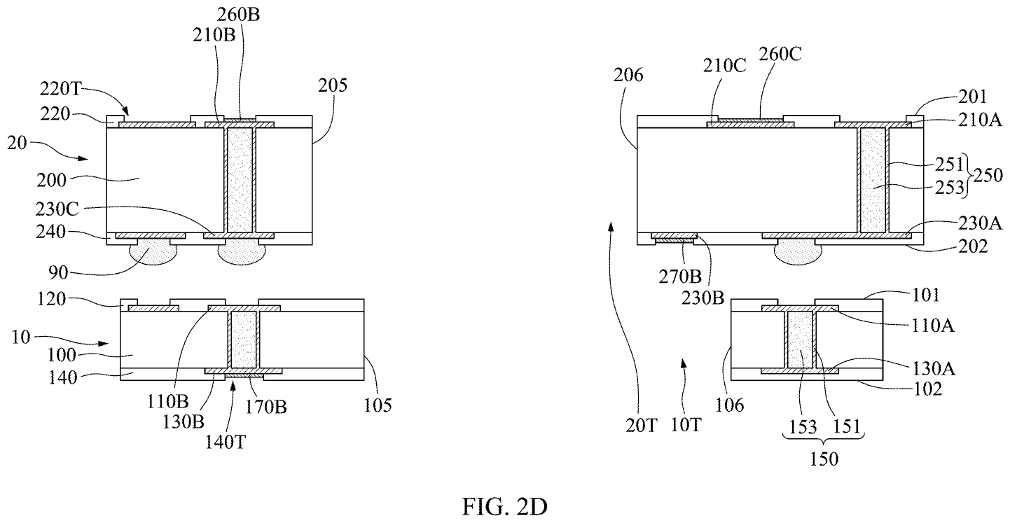

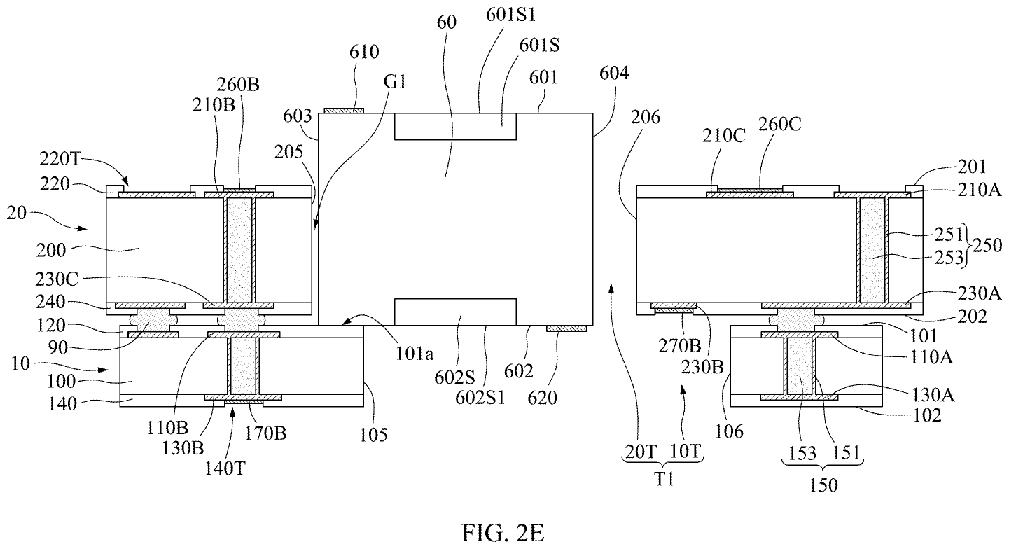

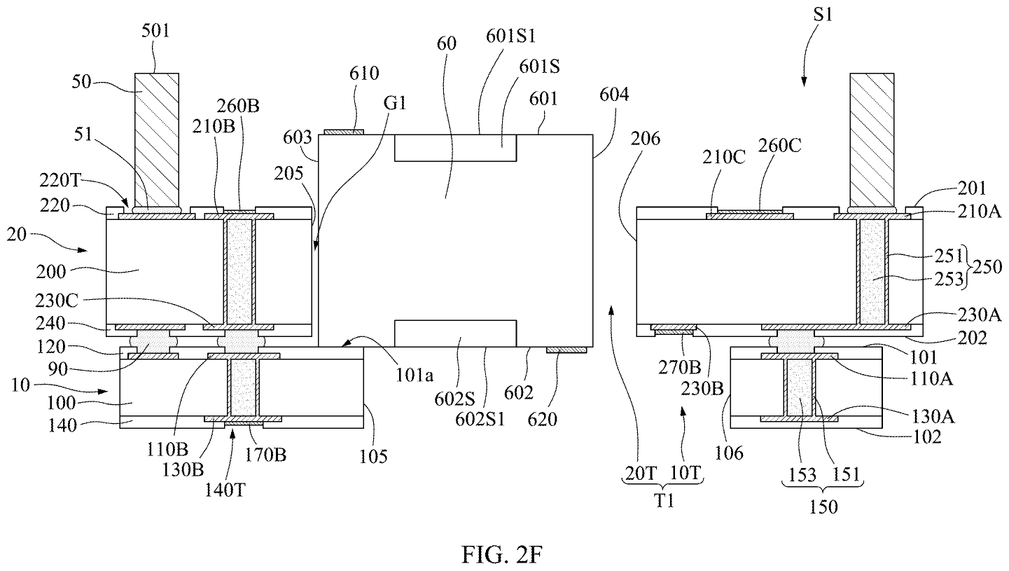

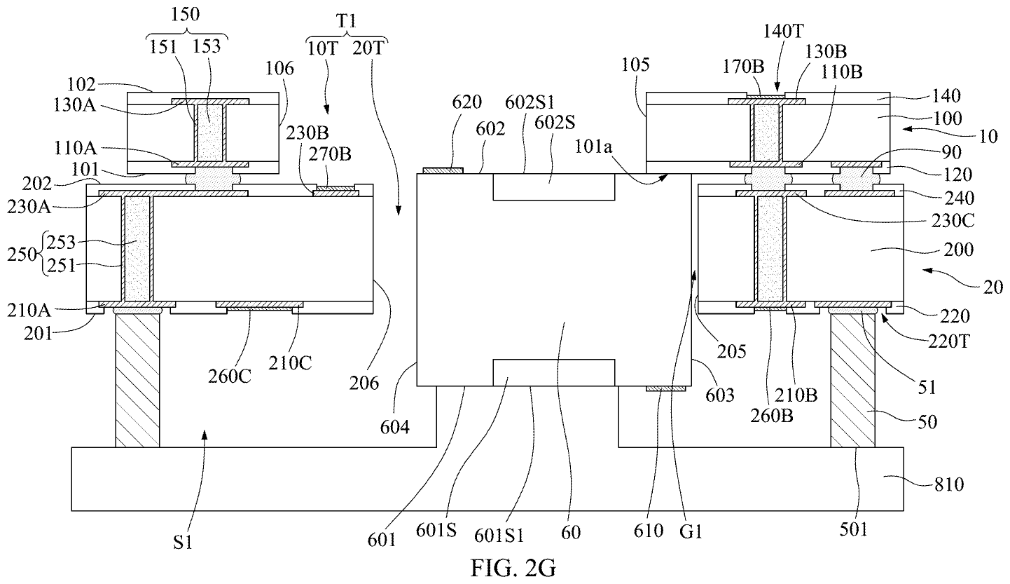

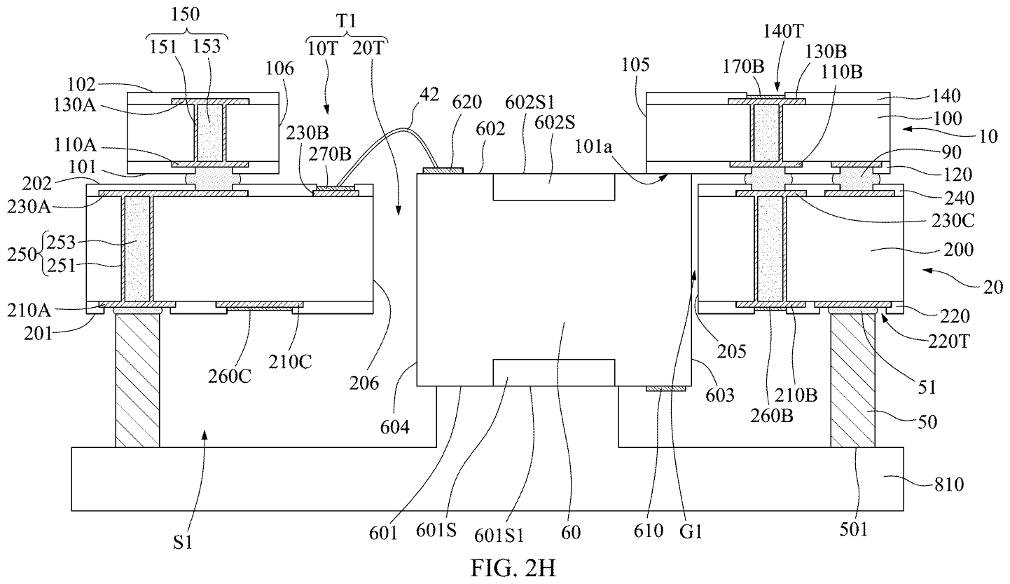

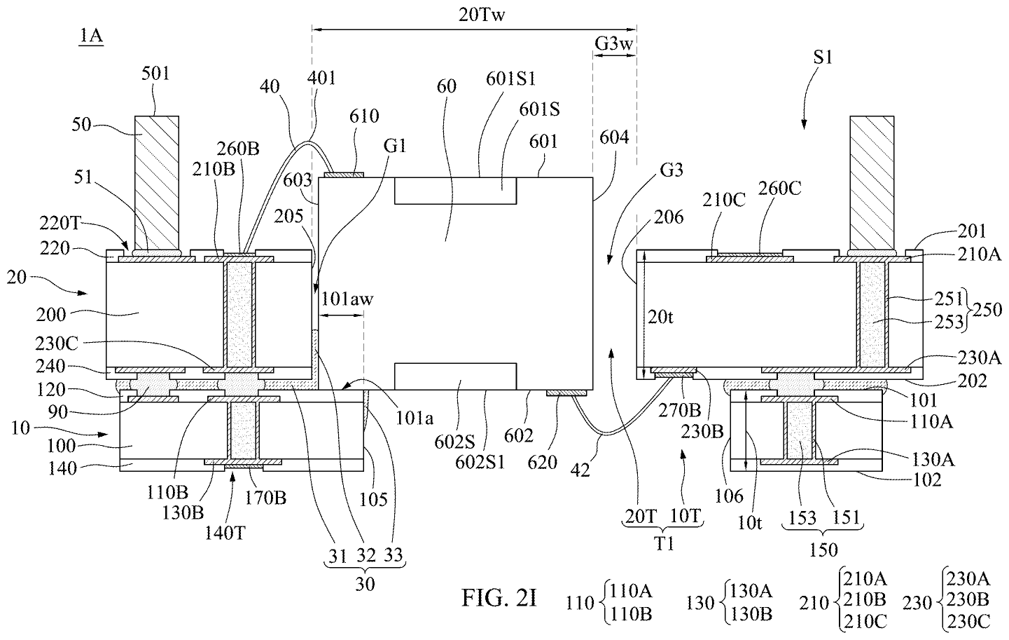

FIG. 2A, FIG. 2B, FIG. 2C, FIG. 2D, FIG. 2E, FIG. 2F, FIG. 2G, FIG. 2H, and FIG. 2I illustrate various stages of an exemplary method for manufacturing a package structure 1A in accordance with some embodiments of the present disclosure.

Referring to FIG. 2A, a substrate 10 including a base layer 100, circuit layers 110 and 130, dielectric layers 120 and 140, and one or more conductive vias 150 may be provided, and a substrate 20 including a base layer 200, circuit layers 210 and 230, dielectric layers 220 and 240, and one or more conductive vias 250 may be provided.

Referring to FIG. 2B and FIG. 2C, FIG. 2B illustrates a cross-section along a line 2A-2A′ in FIG. 2C. A through hole 10T may be formed penetrating the base layer 100 and the dielectric layers 120 and 140, and a through hole 20T may be formed penetrating the base layer 200 and the dielectric layers 220 and 240. The through holes 10T and 20T may be formed by laser drilling, mechanical drilling, or any suitable technique.

Referring to FIG. 2D, connection elements 90 may be formed on a surface 202 (or the bottom surface) of the substrate 20. The connection elements 90 may be or include conductive bumps.

Referring to FIG. 2E, the substrate 20 may be connected to or bonded to the substrate 10 by the connection elements 90. In some arrangements, the substrate 20 is guided toward the substrate 10 until the connection elements 90 contact the substrate 10, and then a thermal treatment (e.g., a reflow operation) may be performed on the connection elements 90 to connect or bond the substrate 20 to the substrate 10 by the connection elements 90. The substrates 10 and 20 collectively construct a substrate structure including a through hole T1 formed from the through holes 10T and 20T. The through hole T1 includes a stepped sidewall structure T11 with a step surface (e.g., a portion 101a of the surface 101 of the substrate 10 exposed by the through hole 20T).

Referring to FIG. 2F, a chip 60 including pads 610 and 620 may be disposed in the through hole T1 supported by the stepped sidewall structure T11, and a spacer structure 50 may be adhered or attached to the substrate 20. In some arrangements, the surface 602 of the chip 60 may contact a portion 101a of the top surface (e.g., the surface 101) of the substrate 10. In some arrangements, the surface 101 of the substrate 10 may be substantially aligned with the surface 602 of the chip 60. In some arrangements, the chip 60 may be separated from the sidewall of the through hole 20T by a gap G1. In some arrangements, the spacer structure 50 is adhered to the portion 210A of the circuit layer 210 by an adhesive element 51 exposed by the opening 220T of the dielectric layer 220.

Referring to FIG. 2G, the structure illustrated in FIG. 2F may be flipped over and disposed on a carrier 810. In some arrangements, the carrier 810 includes a plate portion supporting the spacer structure 50 and a protruded portion supporting the chip 60.

Referring to FIG. 2H, a conductive wire 42 may be provided or formed over the surface 102 of the substrate 10 to connect the circuit layer 130 to the pad 620 of the chip 60. In some arrangements, the conductive wire 42 is entirely received within the through hole 10T of the substrate 10.

Referring to FIG. 21, the structure illustrated in FIG. 2H may be flipped over, such that the substrate 10 may serve as a supporting carrier for the structure to undergo subsequent operations, and the conductive wire 42 may be received within the through hole 10T and protected by the substrate 10. Next, a conductive wire 40 may be provided or formed over the surface 201 of the substrate 20 to connect the circuit layer 210 to the pad 610 of the chip 60, and an adhesive material may be provided to encapsulate the connection elements 90 between the substrate 10 and the substrate 20. In some arrangements, the adhesive material may flow into the gap G2 between the sidewall (e.g., the sidewall 205) of the through hole 20T and the chip 60. In some arrangements, the adhesive material may further flow downward to cover a portion of the sidewall 105 of the through hole 10T. Next, a curing operation may be performed to cure the adhesive material to form an adhesive layer 30. As such, the package structure 1A illustrated in FIG. 1A may be formed.

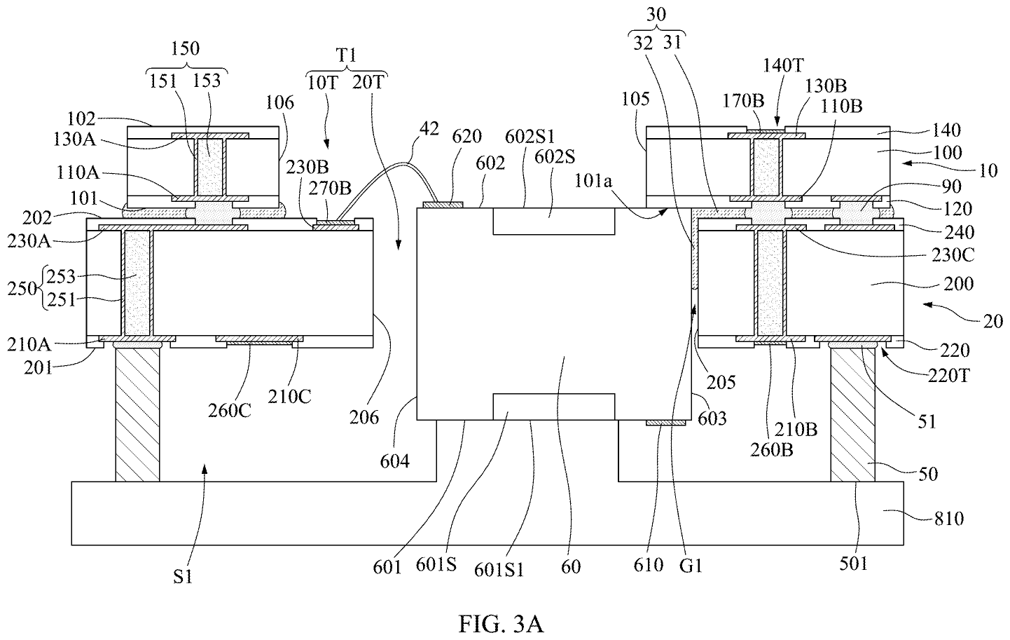

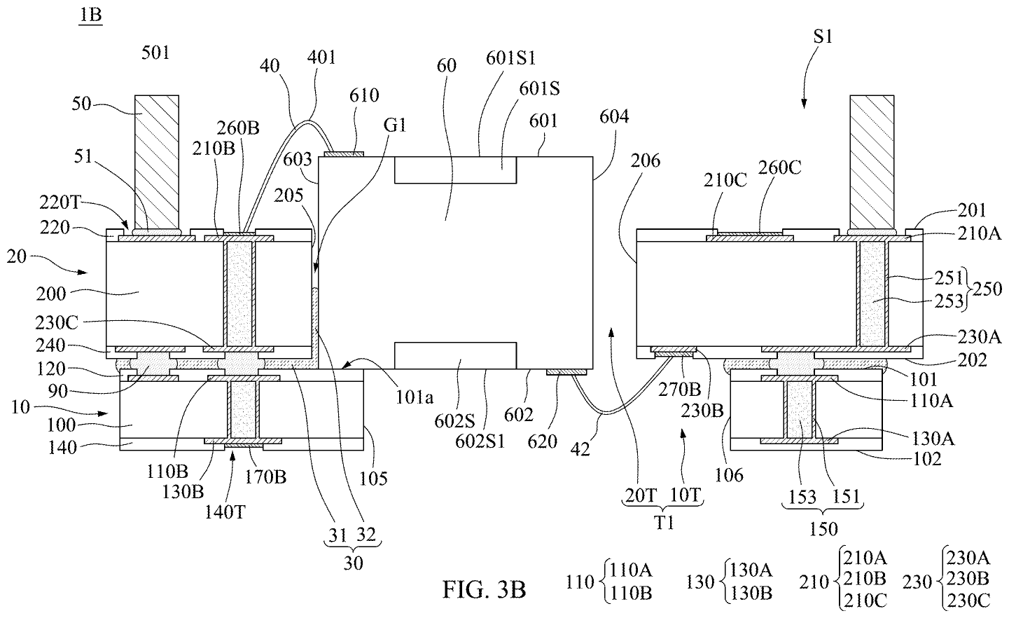

FIG. 3A, and FIG. 3B illustrate various stages of an exemplary method for manufacturing a package structure 1B in accordance with some embodiments of the present disclosure.

Referring to FIG. 3A, operations similar to those illustrated in FIG. 2A to FIG. 2H may be performed to form a structure similar to that illustrated in FIG. 2H. After a conductive wire 42 is provided or formed over the surface 102 of the substrate 10 to connect the circuit layer 130 to the pad 620 of the chip 60 as illustrated in FIG. 3A, an adhesive material may be provided to encapsulate the connection elements 90 between the substrate 10 and the substrate 20. In some arrangements, the adhesive material may flow downward into the gap G2 between the sidewall (e.g., the sidewall 205) of the through hole 20T and the chip 60. Next, a curing operation may be performed to cure the adhesive material to form an adhesive layer 30. Since the curing operation is performed when the substrate 10 is stacked over the adhesive material, the adhesive material does not flow to cover a portion of the sidewall 105 of the through hole 10T.

Referring to FIG. 3B, the structure illustrated in FIG. 3A may be flipped over, and a conductive wire 40 may be provided or formed over the surface 201 of the substrate 20 to connect the circuit layer 210 to the pad 610 of the chip 60. As such, the package structure 1B illustrated in FIG. 1B may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a lower substrate defining a lower through hole;
an upper substrate over the lower substrate and defining an upper through hole connected to the lower through hole, wherein a portion of a top surface of the lower substrate is exposed by the upper through hole; and
a chip at least partially accommodated by the upper through hole and supported by the portion of the top surface of the lower substrate.

2. The package structure as claimed in claim 1, wherein the upper substrate comprises a first pad on a bottom surface of the upper substrate, and the first pad is exposed by the lower through hole.

3. The package structure as claimed in claim 2, wherein the upper substrate further comprises a second pad on a top surface of the upper substrate, the chip comprises an upper pad and a lower pad at an opposite side of the chip to the upper pad, and the package structure further comprises a first wire connecting the upper pad to the second pad and a second wire connecting the lower pad to the first pad.

4. The package structure as claimed in claim 3, wherein a distance between the upper substrate and a bottom surface of the lower substrate is greater than a distance between the upper substrate and a bottom apex of the second wire.

5. The package structure as claimed in claim 3, wherein a curvature change of the first wire is greater than a curvature change of the second wire.

6. The package structure as claimed in claim 1, wherein an elevation of a bottom surface of the chip is lower than a bottom surface of the upper substrate with respect to the top surface of the lower substrate.

7. The package structure as claimed in claim 1, further comprising a protective element on a top surface of the upper substrate and configured to prevent the chip from impacts from outside of the protective element.

8. The package structure as claimed in claim 7, further comprising a wire electrically connecting the chip to the upper substrate, wherein a top end of the protective element is higher than a top apex of the wire with respect to the top surface of the upper substrate.

9. A package structure, comprising:
a substrate structure defining a through hole including a stepped sidewall structure; and
a chip disposed in the through hole and supported by the stepped sidewall structure,
wherein in a top view perspective, a center axis of the substrate structure is non-parallel to a center axis of the chip.

10. The package structure as claimed in claim 9, wherein in the top view perspective, the chip has a first side surface, a second side surface adjacent to the first side surface, and a third side surface adjacent to the first side surface, and the package structure further comprises an adhesive layer between a sidewall of the substrate structure and the first side surface, the second side surface, and the third side surface of the chip.

11. The package structure as claimed in claim 10, wherein in the top view perspective, the adhesive layer comprises a first portion adjacent to the second side surface and a second portion adjacent to the third side surface, and the first portion and the second portion have different lengths.

12. The package structure as claimed in claim 11, wherein in the top view perspective, the first portion of the adhesive layer has a non-uniform width.

13. The package structure as claimed in claim 11, further comprising a conductive wire connecting the chip to the substrate structure, wherein in the top view perspective, an extending direction of the conductive wire is non-parallel to the center axis of the substrate structure.

14. A package structure, comprising:
a first substrate defining a first through hole;
a second substrate over and physically spaced apart from the first substrate, wherein the second substrate defines a second through hole, and a center axis of the first through hole is misaligned with a center axis of the second through hole in a cross-sectional view perspective; and
a chip disposed in the second through hole.

15. The package structure as claimed in claim 14, wherein the first substrate and the second substrate collectively define a stepped structure.

16. The package structure as claimed in claim 15, further comprising an adhesive layer between the first substrate and the second substrate.

17. The package structure as claimed in claim 16, wherein the adhesive layer covers a portion of a lateral surface of the chip.

18. The package structure as claimed in claim 16, wherein the adhesive layer covers a portion of a lateral surface of the stepped structure.

19. The package structure as claimed in claim 15, further comprising a conductive via structure electrically connecting the first substrate to the second substrate.

20. The package structure as claimed in claim 19, wherein a thickness of the second substrate is greater than a thickness of the first substrate.
